(19) United States
(12) Patent Application Publication
(10) Pub. No.: US 2007/0264827 A1
(43) Pub. Date: Nov. 15, 2007

(54) Method for achieving uniform chemical mechanical polishing in integrated circuit manufacturing

(75) Inventors: Yi Ding, Sunnyvale, CA (US); Xinyu Zhang, Palo Alto, CA (US); Wee-chen Gan, Cupertino, CA (US)

Correspondence Address: MACPHERSON KWOK CHEN & HEID LLP, 2033 GATEWAY PLACE, SUITE 400, SAN JOSE, CA, 95110, US

(73) Assignee: ProMOS Technologies Pte. Ltd.

(21) Appl. No.: 11/431,255

(22) Filed: May 9, 2006

(51) Int. Cl. H01L 21/461; H01L 21/302

(52) U.S. Cl. 438/692

(57) ABSTRACT

A method for planarizing a surface in an integrated circuit manufacturing process provides a first film of a first material over a non-uniform surface, such as a surface including isolation trenches. The first material includes, for example, a polysilicon layer to be used to form floating gates in a non-volatile memory integrated circuit. A second film, which is a sacrificial film formed using a second material, such as silicon oxide, is then provided over the first film. Partial removal of the second film is carried out using chemical mechanical polishing until a portion of the first film is exposed using a first slurry that is selective to the first material. Thereafter, the remaining layer of the second film is removed, along with planarization of the surface, using a second slurry that is less selective, i.e., has a selectivity of the first film to the second film that is less than a predetermine value (e.g., 2:1).

### BACKGROUND OF THE INVENTION

1. Field of the Invention

The present invention relates to using chemical-mechanical polishing (CMP) in integrated circuit manufacturing.

2. Discussion of the Related Art

In an integrated circuit, such as a floating gate non-volatile memory integrated circuit, complicated structures of patterned conductor and insulator films are created on a semiconductor wafer. To allow many such films to be provided, it is advantageous that certain films provide planar surfaces to facilitate formation of additional films that are to be provided over those surfaces. One process that is extensively used in integrated circuit manufacturing is chemical mechanical polishing (CMP). In CMP, a planar surface is provided by polishing the surface with a chemical abrasive (“slurry”). However, it is observed that the conductor and the insulator patterns exposed on a surface of the wafer affects the effectiveness of CMP. The resulting non-uniformity, such as “dishing”, adversely affects manufacturing yield. For example, FIG. 1 shows cross sections of regions 100a and 100b of a semiconductor wafer at conventional step (“poly CMP”) in the integrated circuit manufacturing process. In region 100a, as are typical of the “array” or “periphery” areas where the memory cells and the control circuits are respectively located, the features are “dense” (e.g., conductor lines are 70˜250 nm apart). As shown in FIG. 1, dielectric isolation trenches 101 and 101b filled with a high density plasma (HDP) oxide are positioned about 70˜250 nm apart in region 100a. In region 100b, however, where the features are “loose” (e.g., at a large capacitor), isolation trenches 101c and 101d may be 100 urn or more apart. Such a difference in feature density can affect the planarity resulting from applying a CMP process on an overlaying layer, such as polysilicon layer 102.

In one instance, as measured from scanning electron microscope (SEM) images of cross sections at the array, periphery and large capacitor areas of a floating gate non-volatile memory integrated circuit taken immediately after the poly CMP step, the thicknesses of the polysilicon layer remaining in the array, periphery and large capacitor areas were found to be 173 nm, 170 nm and 124 nm, respectively. Thus, a significant difference of approximately 50 nm is found between the “dense” and “loose” feature areas. The variations are very difficult to control in the manufacturing process.

Thus, there is a need for a low-cost CMP process that provides high uniformity across dense and loose feature regions.

### SUMMARY

This section is a brief summary of some features of the invention. The invention is defined by the appended claims which are incorporated into this section by reference.

According to one embodiment of the present invention, a method for planarizing a surface in an integrated circuit manufacturing process provides a first film of a first material over a non-uniform surface, such as a surface including isolation trenches. The first material includes, for example, a polysilicon layer to be used to form floating gates in a non-volatile memory integrated circuit. A second film, which is a sacrificial film formed using a second material, such as silicon oxide, is then provided over the first film. Partial removal of the second film is carried out using chemical mechanical polishing until a portion of the first film is exposed. This CMP step may use a first slurry that is selective to the first material, leaving the second film over valley areas. Thereafter, the remaining portions of the second film are removed, along with planarization of the surface, using a second slurry that is less selective than the first slurry, or selective to the second film and less selective to the first film.

According to one embodiment of the present invention, the 2-step CMP process of the present invention is applied to a surface provided over regions including isolation trenches. In that instance, both the sacrificial film and the material filling the isolation trenches are silicon oxides.

To provide a planar surface on a polysilicon film, the first slurry may include cerium oxide, and the second slurry may include silica.

Other features are described below.

### BRIEF DESCRIPTION OF THE DRAWINGS

FIG. 1 shows cross sections of regions 100a and 100b of a semiconductor wafer at one step in the integrated circuit manufacturing process.

FIGS. 2-7 illustrate steps in an integrated circuit manufacturing process leading up to a step that uses a 2-step CMP process, in accordance with one embodiment of the present invention.

FIG. 8 shows sacrificial layer 413 (e.g., a deposited silicon oxide) provided over polysilicon layer 410, in accordance with one embodiment of the present invention.

FIG. 9 shows partial removal of sacrificial layer 413 after a first CMP step, in accordance with one embodiment of the present invention.

FIG. 10 shows desired planar surface after a second CMP step, in accordance with one embodiment of the present invention.

FIG. 11 shows, after the 2-step CMP process, layer 410, planarity is achieved on the surface of polysilicon layer 410, in accordance with one embodiment of the present invention.

FIG. 12 is a circuit diagram of an array of non-volatile memory cells which can be fabricated using the manufacturing process of the present invention.

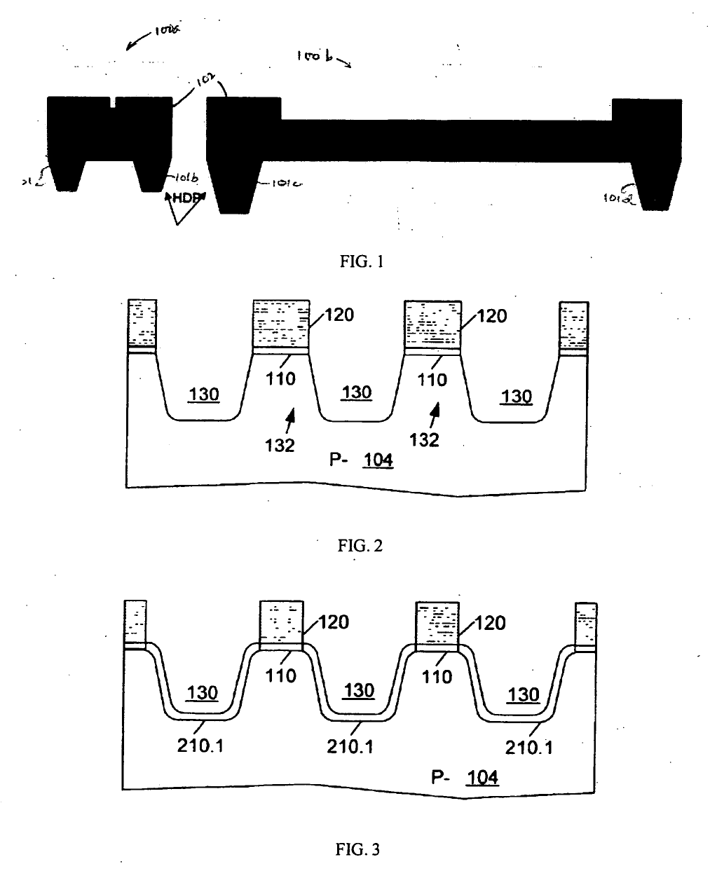

### DESCRIPTION OF PREFERRED EMBODIMENTS

This section describes some embodiments to illustrate the invention. The invention is not limited to these embodiments. The materials, conductivity types, layer thicknesses and other dimensions, circuit diagrams, and other details are given for illustration and are not limiting. In the detailed description below, the present invention is described for illustration purpose only by an application in a manufacturing process for a non-volatile memory integrated circuit. However, the present invention is applicable not only to manufacturing processes for non-volatile memory integrated circuits, it is applicable to most manufacturing processes of integrated circuits, including logic integrated circuits, and dynamic memory (e.g., DRAMs) and static memory (e.g., SRAMs) integrated circuits.

In some embodiments, the memory array fabrication starts with substrate isolation. FIGS. 2-7 illustrate steps in an integrated circuit manufacturing process leading up to a step that uses a 2-step CMP process, in accordance with one embodiment of the present invention. These figures illustrate one variation commonly practiced in memory technology. Where conventional steps are mentioned below, their details may be found, for example, in U.S. Pat. No. 6,355,524 (the “'524 Patent”), entitled “Non-volatile Memory Structures and Fabrication Methods,” issued Mar. 12, 2002 to H. T. Tuan et al., or in U.S. Pat. No. 6,743,675 (the “'675 Patent”), entitled “Floating Gate Memory Fabrication Methods Comprising a Field Dielectric Etch with a Horizontal Etch Component,” issued on Jun. 1, 2004 to Ding. The '524 Patent and the '675 Patent are hereby incorporated by reference to provide background information.

In this embodiment, field dielectric regions may be fabricated by shallow trench isolation (“STI”) technology. Initially, as shown in FIG. 2, a P-type doped region is formed in a monocrystalline semiconductor substrate 104. Silicon dioxide 110 (pad oxide) is then formed on substrate 104 by thermal oxidation or another suitable technique. Silicon nitride 120 is then deposited on silicon oxide 110 and patterned photolithographically, using a photoresist mask (not shown) to define shallow isolation trenches 130. Silicon nitride 120, silicon oxide 110 and substrate 104 are then etched through the openings of the photoresist mask. Trenches 130 (“STI trenches”) are formed in the substrate as a result (FIG. 2). An exemplary depth of trenches 130 is 0.2˜0.3 μm measured from the top surface of the substrate 104. Other depths are possible. Trenches 130 will be filled with one or more dielectric materials to provide isolation between active areas 132 of substrate 104. In FIG. 2, the trenches have sloping sidewalls, and the trenches are wider at the top than at the bottom. In some embodiments, the trenches have vertical sidewalls, or the trenches are wider at the bottom. The invention is not limited by any shape of the trenches.

Silicon nitride 120 is subjected to a wet etch (e.g., using HF/glycerol) to recess the vertical edges of nitride layer 120 and silicon oxide layer 110 away from trenches 130. This step reduces the aspect ratio of the holes that will be filled with dielectric 210 (these holes are formed by the openings in nitride 120 and oxide 110 and by the trenches 130). The lower aspect ratio facilitates filling these holes.

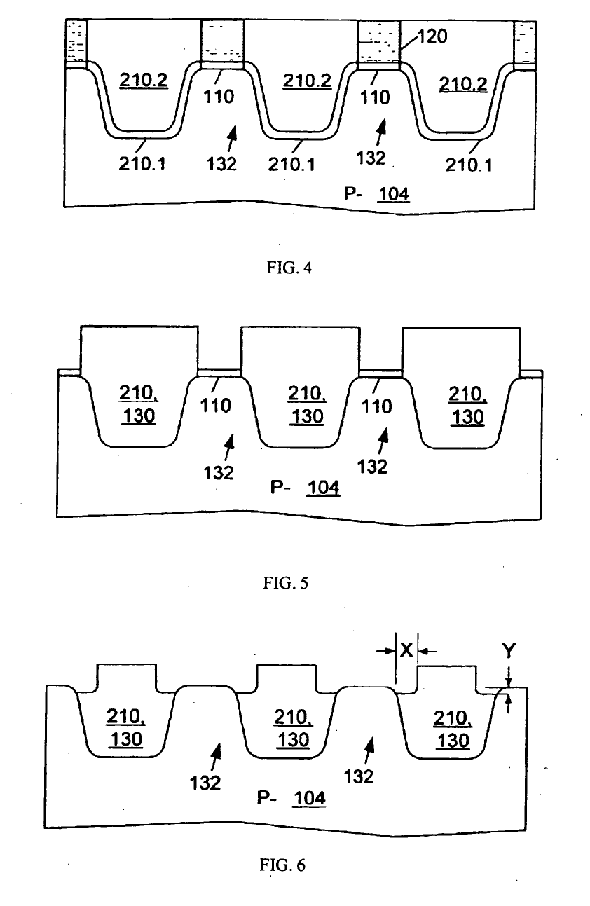

A thick layer 210.1 of silicon dioxide (e.g., 100˜200 Å) is thermally grown on the exposed silicon surfaces to round the edges of trenches 130 (FIG. 3). Silicon dioxide 210.2 (FIG. 4) is deposited by a high density plasma process. Silicon oxide 210.2 fills the trenches and initially covers the nitride 120. Silicon oxide 210.2 may be polished by a CMP process that stops on nitride 120. A planar top surface may thus be provided.

In the subsequent figures, the layers 210.1, 210.2 are shown as a single layer 210. This dielectric silicon oxide 210 will be referred to as STI dielectric or, more generally, field dielectric. Silicon nitride 120 is then removed selectively to silicon oxide 210 (FIG. 5) using, for example, a wet etch (e.g. with phosphoric acid). Silicon oxide 210 is etched (FIG. 6) using, for example, an isotropic wet etch selective to silicon nitride. A buffered oxide etch or a dilute HF (DHF) etch may be used. This etch may include a horizontal component that causes the sidewalls of dielectric 210 to be laterally recessed away from active areas 132 and that may also remove the silicon oxide 110.

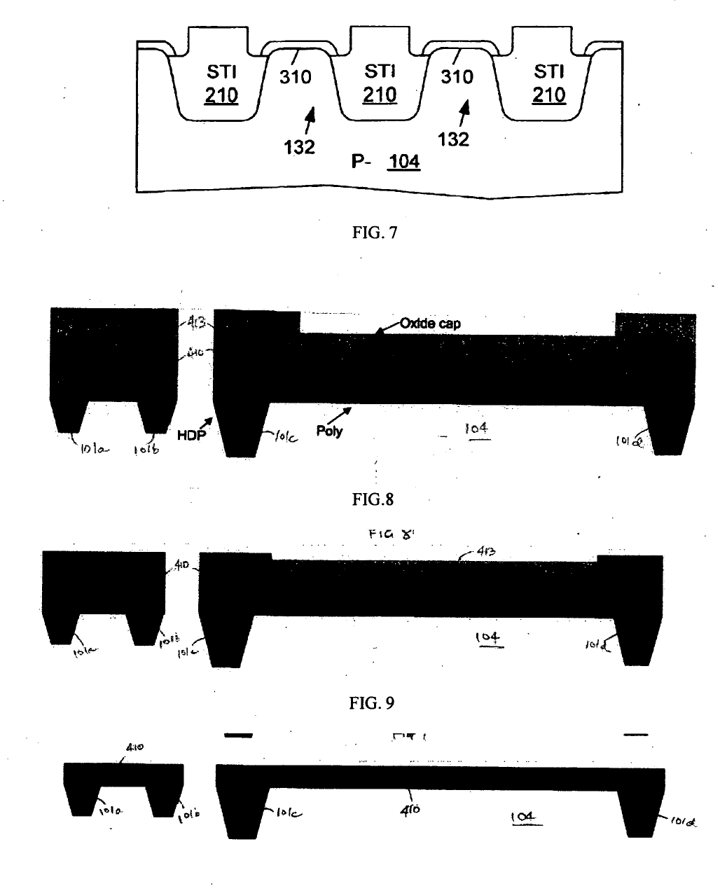

The top surface of dielectric 210 may be laterally offset from the top surface of active areas 132 by an amount X=300 Å at the end of this etch, for example. Some of dielectric 210 may be etched out of the trenches 130 near the active areas 132, and the sidewalls of trenches 130 may become exposed at the top, but this is not necessary. The trench sidewalls may be exposed to a depth Y=300 Å, for example. As shown in FIG. 7, silicon dioxide 310 (tunnel oxide) is thermally grown on the exposed areas of substrate 104. An exemplary thickness of tunnel oxide 310 is 80˜100 Å.

As shown in FIG. 8, conductive polysilicon layer 410 (floating gate polysilicon) is formed over the structure. Polysilicon 410 fills the areas between oxide regions 210 and initially covers the oxide 210. According to one embodiment of the present invention, polysilicon 410 is polished by a 2-step CMP process illustrated in FIGS. 8-10. As shown in FIG. 8, prior to applying CMP, sacrificial layer 413 (e.g., a deposited silicon oxide) is provided over polysilicon layer 410. A first CMP step, using a slurry highly selective to polysilicon 410, is then applied to the surface. For example, a cerium oxide slurry (“ceria”) that has an oxide to polysilicon selectivity of approximately 14:1 may be applied (i.e., a slurry that removes approximately 14 parts of oxide to one part of polysilicon). In one embodiment of the present invention, in this first CMP step, a suitable downward force of 3-7 psi with a back side pressure of 0-3 psi. The slurry flow rate may be set to 50-300 sccm at a platen/carrier speed of 20-100 rpm. This first CMP step may be terminated automatically using end-point detection of polysilicon. Alternatively, this first CMP step may be timed.

FIG. 9 shows partial removal of sacrificial layer 413 after the first CMP step. As shown in FIG. 9, a substantially planar surface is achieved. After an in-situ or ex-situ cleaning step to remove the remaining selective slurry, a second CMP step is carried out using a relatively non-selective slurry. For example, a silica slurry of polysilicon to oxide selectivity of approximately 2:1 may be applied (i.e., a slurry that removes approximately 2 parts of polysilicon for each part of oxide removed). In one embodiment of the present invention, in this second CMP step, a suitable downward force of 3-7 psi with a back side pressure of 0-5 psi may be applied. The slurry flow rate may be set to 50-300 sccm at a platen/carrier speed of 20-100 rpm. This second CMP step may be stopped by automatic end-point detection of the high density plasma oxide (i.e., dielectric 210) or timed. FIG. 10 shows a desired planar surface resulting from the second CMP step, in accordance with the present invention.

In one embodiment, SEM images taken at various regions of a semiconductor surface after carrying out the above 2-step CMP process showed superior planarity results in both “dense” and “loose” regions. In one instance, the first CMP step was carried out using a high-selectivity ceria slurry (e.g., oxide to polysilicon selectivity of 14:1) for 100 seconds, followed by the second CMP step using a relatively-low selectivity silica slurry (e.g. polysilicon to oxide selectivity of 2:1) for 75 seconds. The remaining polysilicon layers in array, periphery and large capacitor areas were measured to have a thicknesses of 162 nm, 161 nm and between 167-182 nm, respectively. The non-uniformity of the 2-step process is therefore significantly reduced from that exhibited in the prior art. The non-uniformity may be reduced further by adjusting the thickness of the sacrificial film.

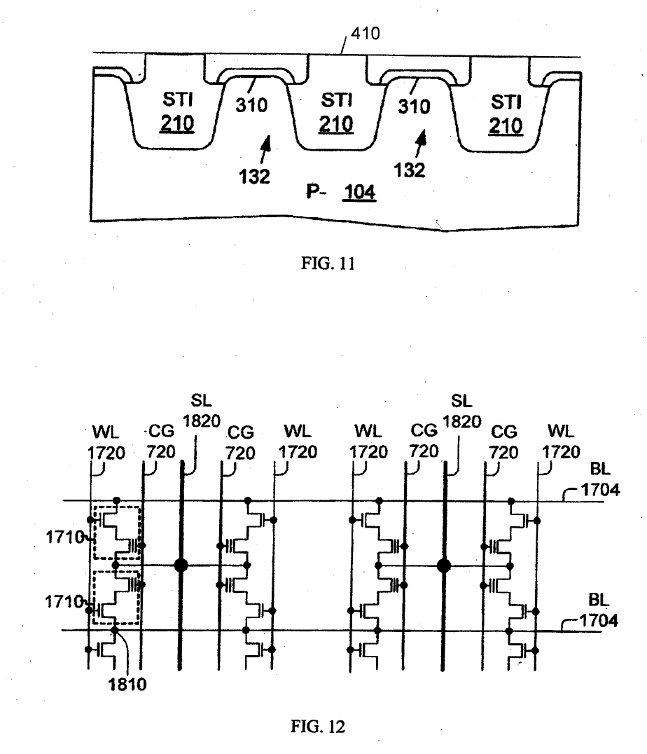

After the 2-step CMP process, polysilicon layer 410 is made conductive by doping. (Alternatively, polysilicon layer 410 may be doped in-situ at formation). The horizontal top surface of polysilicon 410 projects over the isolation trenches 130 laterally beyond the areas 132, as shown in FIG. 11. Polysilicon 410, which is to be used to form floating gates in one application, abut dielectric regions 210. FIG. 11 illustrates the surface of the semiconductor wafer after the 2-step CMP process, in accordance with one embodiment of the present invention. In FIG. 11, the floating gate sidewalls extend laterally outward beyond areas 132 as the sidewalls are traced upward. Different sidewall profiles can be obtained as defined by the sidewall profiles of dielectric 210.

A wide range of floating gate memories (e.g., NAND, NOR or AND type flash memories) can be made using the teachings of the present invention, including stacked gate, split gate and other cell structures, flash and non-flash EEPROMs, and other memory types. An example split gate flash memory array is illustrated in FIG. 12. This memory array is similar to one disclosed in the aforementioned '524 Patent.

Fabrication of the non-volatile memory integrated circuit may be completed using the steps shown and discussed in conjunction with FIGS. 16-50 (e.g., col. 11, lines 35 et seq,) in the aforementioned '524 Patent. Alternatively, the remaining fabrication steps can follow that shown and discussed in FIGS. 15-19B and incorporated by reference from the '675 Patent.

The 2-step CMP process is also applicable to other fabrication steps where CMP is required. Also, the 2-step CMP process is applicable not only to structures including trenches, whether filled with oxide or another material, but is applicable also to processes using dual damascene structures or single damascene structures (e.g., in conductor layers, where the trenches with silicon oxide, silicon nitride or silicon oxynitride sidewalls are filled with a conductive material, such as a polysilicon or a metal).

The above detailed description is provided to illustrate the specific embodiments of the present invention and is not intended to be limiting. Numerous variations and modifications within the scope of the present invention are possible. The present invention is set forth in the appended claims.

We claim:

1. A method for planarizing a surface in a integrated circuit manufacturing process, comprising:
providing a first film of a first material over a surface;
providing a second film of a second material over the first film;
chemically and mechanically polishing the second film until a portion of the first film is exposed using a first slurry that is selective to the first material; and
chemically and mechanically polishing the second film using a second slurry.

2. A method as in claim 1, wherein the second slurry is substantially non-selective relative to the first material and the second material.

3. A method as in claim 1, wherein the second slurry has a selectivity of the second material to the first material that is less than a predetermined value.

4. A method as in claim 2, wherein the first material is provided over isolation trenches.

5. A method as in claim 4, wherein the isolation trenches are filled with a material chemically the same as the second material.

6. A method as in claim 1, wherein the first material comprises polysilicon.

7. A method as in claim 1, wherein the second material comprises silicon oxide.

8. A method as in claim 1, wherein the first slurry comprises cerium oxide.

9. A method as in claim 1, wherein the second slurry comprises silicon oxide.

10. A method as in Claim 1, wherein the first material is provided over isolation trenches.
